(19) United States
(12) Patent Application Publication
(10) Pub. No.: US 2007/0069237 A1
(43) Pub. Date: Mar. 29, 2007

(54) Systems for providing electrostatic discharge protection

(75) Inventors: Ching-Wei Lin, Tou-Yuan City (TW); Ting-Kuo Chang, Hsin-Chu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Toppoly Optoelectronics Corp.

(21) Appl. No.: 11/238,970

(22) Filed: Sep. 29, 2005

(51) Int. Cl. H01L 29/74

(52) U.S. Cl. 257/173

(57) ABSTRACT

Systems for providing electrostatic discharge (ESD) protection. One of the Systems has a plurality of first-type thin film diode elements coupled to each other in series, and a plurality of second-type thin film diode elements coupled to each other in series. The first-type thin film elements are electrically connected to a signal line between an input end and a main circuit, and the second-type thin film diode elements are electrically connected to the signal line between the input end and the main circuit.

### BACKGROUND OF THE INVENTION

1. Field of the Invention

The present invention relates to electrostatic discharge (ESD) protection, and more particularly, to a system for providing ESD protection.

2. Description of the Prior Art

Electrostatic discharge (ESD) is a significant problem in integrated circuits in many kinds of electronic products. Take a liquid crystal display (LCD) panel for example. An LCD panel normally includes two glass substrates that are non-conductive. Thus, abruptly generated ESD cannot spread over the glass substrates. Such an ESD may cause damage to the devices formed on the glass substrate. Consequently, an ESD protection circuit is normally incorporated into such a display panel to prevent the ESD damage.

With reference to FIG. 1, FIG. 1 is a schematic diagram of a conventional ESD protection circuit 10 adopted for use in a display panel. As shown in FIG. 1, the conventional ESD protection circuit 10 includes a p-type thin film transistor 12 and an n-type thin film transistor 14. The p-type thin film transistor 12 and the n-type thin film transistor 14 are electrically connected to a signal line 16, e.g. a scan line or a data line, between an input end 18 and a main circuit 20 of a display panel. The p-type thin film transistor 12 includes a gate 121, a drain 122, and a source 123, wherein the gate 121 and the source 123 are short-circuited. The n-type thin film transistor 14 includes a gate 141, a source 142, and a drain 143, wherein the gate 141 and the drain 143 are short-circuited. In addition, the source 123 of the p-type thin film transistor 12 and the drain 143 of the n-type thin film transistor 14 are respectively electrically connected to a relatively highest voltage 22 and a relatively lowest voltage 24.

With additional reference to FIG. 2, FIG. 2 is an equivalent circuit diagram of the conventional ESD protection circuit 10. As shown in FIG. 2, by virtue of the connection illustrated, while an ESD pulse appears, the p-type thin film transistor 12 and the n-type thin film transistor 14 act as two p-n junction diode elements. Thus, ESD protection functions are provided to the main circuit 20 of the display panel. Specifically, either the p-type thin film transistor 12 or the n-type thin film transistor 14 is forward biased when a positive or a negative voltage is applied to the input end 18. That is, when a pulse due to ESD inputs into the signal line 18, the p-type thin film transistor 12 or the n-type thin film transistor 14 is forward biased, and therefore the pulse does not damage the main circuit 20 of the display panel.

The conventional ESD protection circuit 10 suffers from some problems as well. With additional reference to FIG. 3, FIG. 3 is a schematic chart illustrating the relation between the turn-on current (Ion) and the voltage difference between drain and source (Vds) of the conventional ESD protection circuit 10. As previously described, the gate 121 and the source 123 are short-circuited, and therefore the p-type thin film transistor 12 is operated in a saturation region. Likely, the gate 141 and the drain 143 are short-circuited, and therefore the n-type thin film transistor 14 is operated in a saturation region. Accordingly, for both the p-type thin film transistor 12 and the n-type thin film transistor 14, the turn-on current is proportional to the square of the voltage difference (Vds) between the drain 122 and the source 123, or the voltage difference (Vds) between the drain 143 and the source 142 as shown in FIG. 3.

The increasing speed of the turn-on current with respect to the voltage difference between the drain and the source is not sufficient for the conventional ESD protection circuit 10. Thus, the ESD protection effect needs to be improved.

### SUMMARY OF THE INVENTION

Systems for providing electrostatic discharge (ESD) protection are provided.

An embodiment of such a system comprises an ESD protection circuit for protecting a main circuit. The main circuit includes at least a signal line having an input end. The ESD protection circuit includes a plurality of first-type thin film diode elements coupled to each other in series, and the first-type thin film diode elements are electrically connected to the signal line between the input end and the main circuit at one end.

Another embodiment of such a system comprises a first type of thin film diode elements. The ESD protection circuit of the present invention is characterized by having the following features. The first-type thin film diode elements are thin film diode elements formed on a substrate of a display panel by thin film and implantation techniques. Thus, the thin film diode elements are not thin film transistors.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional ESD protection circuit adapted for use in a display panel.

FIG. 2 is an equivalent circuit diagram of the conventional ESD protection circuit of FIG. 1.

FIG. 3 is a chart illustrating the relation between the turn-on current (Ion) and the voltage difference between drain and source (Vds) of the conventional ESD protection circuit of FIG. 1.

FIG. 4 is a schematic diagram of an embodiment of an ESD protection circuit for protecting a main circuit.

FIG. 5a schematically illustrates a top view of an embodiment of a p⁺-i-n⁺ diode element.

FIG. 5b schematically illustrates a top view of another embodiment of a p⁺-i-n⁺ diode element.

FIG. 6 is a chart illustrating the relation between turn-on current and cross voltage of the p⁺-i-n⁺ diode element of an embodiment of an ESD protection circuit.

FIG. 7 is a schematically, cross-sectional view of another embodiment of a p⁺-i-n⁺ diode.

FIG. 8 to FIG. 13 are schematic diagrams of additional embodiments of thin film diode elements.

FIG. 14 is a schematic diagram illustrating an electronic device incorporating an embodiment of an ESD protection circuit.

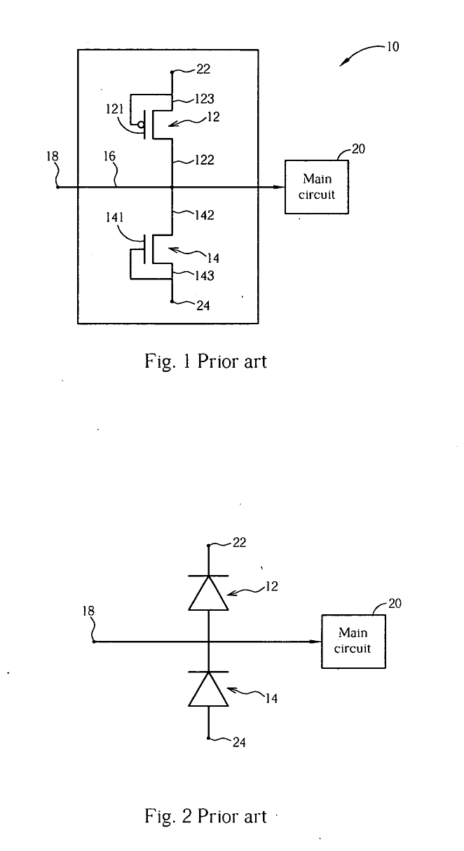

### DETAILED DESCRIPTION

With reference to FIG. 4, FIG. 4 is a schematic diagram of an embodiment of an ESD protection circuit 50 for protecting a main circuit 60. As shown in FIG. 4, the ESD protection circuit 50 includes a plurality of first-type thin film diode elements 52 and a plurality of second-type thin film diode elements 54. In this embodiment, the main circuit 60 is a display circuit of a display panel, such as an LCD panel or an OLED panel. In addition, the first-type thin film diode elements 52 and the second-type thin film diode elements 54 are formed on a substrate of the display panel by thin film and implantation techniques.

The first-type thin film diode elements 52 are coupled in series, and electrically connected to a signal line 56, e.g. a scan line, a data line, or a control signal line of an integrated driver (not shown) between an input end 58 and the main circuit 60. Also, the second-type thin film diode elements 54 are coupled in series, and electrically connected to the signal line 56 between the input end 58 and the main circuit 60. In addition, the first-type thin film diode elements 52 are electrically connected to a relatively high voltage 62, and second-type thin film diode elements 54 are electrically connected to a relative low voltage 64.

The first-type thin film diode elements 52 and the second-type thin film diode elements 54 can be forward biased by a positive voltage and a negative voltage, respectively. Thus, when a pulse due to ESD or other factors is generated at the input end 58 of the signal line 56, the pulse directly passes through either the first-type thin film diode elements 52 or the second-type thin film diode elements 54, rather than the main circuit 60. Consequently, the main circuit 60 is protected.

The ESD protection circuit 50 is characterized by the following features. First, the first-type thin film diode elements 52 and the second-type thin film diode elements 54 are not thin film transistors, but thin film diode elements. The first-type thin film diode elements 52 and/or the second-type thin film diode elements 54 may be p-i-n diode elements, p⁺-i-n⁺ diode elements, p⁺-p⁻-n⁺ diode elements, p⁺-n⁻-n⁺ diode elements, p⁺-p⁻-i-n⁺ diode elements, p⁺-i-n⁻-n⁺ diode elements, p⁺-p⁻-n⁻-n⁺ diode elements, p⁺-p⁻-i-n⁻-n⁺ diode elements, and so on. Second, the ESD protection circuit 50 includes more than one first-type thin film diode element 52 and more than one second-type thin film diode element 54 corresponding to one signal line 56. This can improve cut-in voltage, and therefore prevent possibilities of test error.

In the following descriptions, an embodiment of a diode element configured as a p⁺-i-n⁺ diode element of an ESD protection circuit is described. In other embodiments, other types of diode elements can be used.

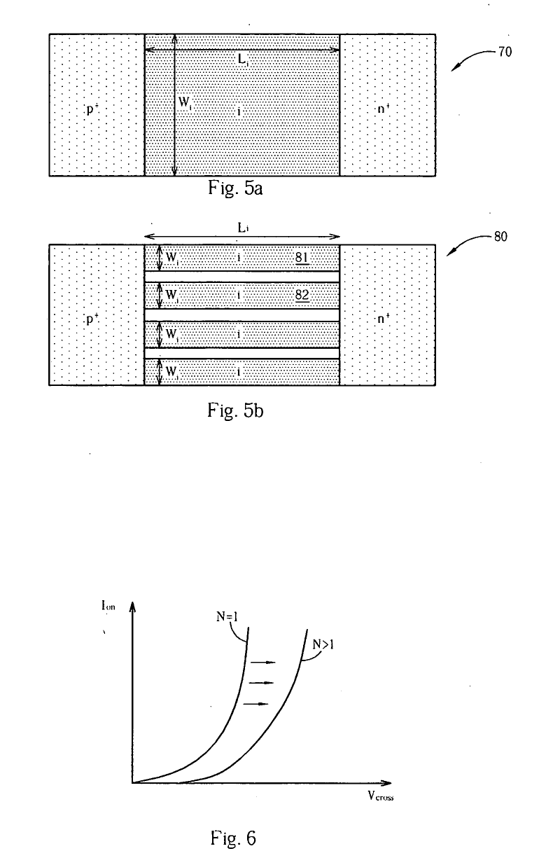

With reference to FIG. 5a and FIG. 5b, FIG. 5a schematically illustrates a top view of a p⁺-i-n⁺ diode element 70, and FIG. 5b schematically illustrates a top view of another p⁺-i-n⁺ diode element 80. As shown in FIG. 5a, the material of the p⁺-i-n⁺ diode element 70 is polysilicon, and the length Li is between 1 to 10 micrometers in this embodiment. When the p⁺-i-n⁺ diode element 70 is forward biased, holes are injected from the p⁺-i interface, and electrons are injected from the i-n⁺ interface. Since the concentration of the injected carriers is far higher than the doped concentration in the i region, the p⁺-i-n⁺ diode element 70 is in a high-injection condition. In such a case, the current density (J) of the p⁺-i-n⁺ diode element 70 can be expressed as follows:
J=qμₙn′E+qμₚp′E=q(μₙ+μₚ)n′E
wherein

n′≈p′ denotes the average density of the carriers injected into the i region;

E denotes the average electric field of the i region;

μₙ denotes the electron mobility;

μₚ denotes the hole mobility; and

q denotes unit electric quantity.

Since n′ and p′ are exponentially proportional to the cross voltage (Vcross) of the p⁺-i-n⁺ diode element 70, the turn-on current (Ion) that is proportional to the current density therefore dramatically increases with the cross voltage. In other words, the turn-on resistance (Ron) of the p⁺-i-n⁺ diode element 70 is substantially reduced, and therefore the ESD protection ability of an ESD protection circuit, such as ESD protection circuit 50 incorporating such a diode element can be improved.

The p⁺-i-n⁺ diode element 70 shown in FIG. 5a has a single channel. However, a multiple channel structure can also be used. As shown in FIG. 5b, the p⁺-i-n⁺ diode element 80 has multiple channels, such as channels 81 and 82. The multiple-channel structure is able to improve heat-dissipation effect, and therefore lower the temperature of the p⁺-i-n⁺ diode element 80. Thus, the multiple-channel structure can improve the performance and reliability of the p⁺-i-n⁺ diode element 80. It is noted that the amounts of channels and the width (Wi) of each channel can be modified where necessary.

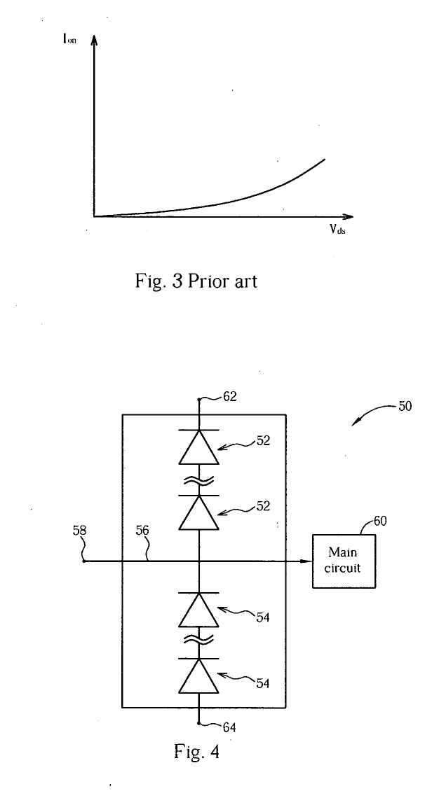

With additional reference to FIG. 6, along with FIG. 3 to FIG. 5, FIG. 6 is a chart illustrating the relation between turn-on current and cross voltage of the p⁺-i-n⁺ diode element 70 of the ESD protection circuit 50. Specifically, the left curve shown in FIG. 6 represents that only one p⁺-i-n⁺ diode element 70 is used (N=1), and the right curve shown in FIG. 6 represents that more than one p⁺-i-n⁺ diode element 70 is used (N>1). As shown in FIG. 6, the slope of the left curve is much steeper than the slope of the curve shown in FIG. 3. This reveals that the turn-on current of the p⁺-i-n⁺ diode element 70 increases much quicker than that of the conventional thin film transistor while the cross voltage increases. As a result, the ESD protection ability of the ESD protection circuit 50 is superior to the conventional ESD protection circuit.

Another concern of an ESD protection circuit is the cut-in voltage. If the cut-in voltage is too low, a test error may occur when an array open/short test is performed on a display panel, incorporating such a circuit. Therefore, the ESD protection circuit can include more than one first-type thin film diode element 52 and more than one second-type thin film diode element 54 corresponding to one signal line 56. When the first-type thin film diode elements 52 and the second-type thin film diode elements 54 are respectively connected in series, the overall cut-in voltage equals the sum of the cut-in voltage of each individual first-type thin film diode elements 52 or the sum of the cut-in voltage of each individual second-type thin film diode elements 54. Consequently, the overall cut-in voltage of the ESD protection circuit 50 is augmented. This can prevent a test error during an array open/short test. As the right curve of FIG. 6 reveals, the overall cut-in voltage increases when more p⁺-i-n⁺ diode elements are connected in series. In addition, by virtue of connecting the p⁺-i-n⁺ diode elements in series, the breakdown voltage of the ESD protection circuit 50 is increased and the leakage current is reduced.

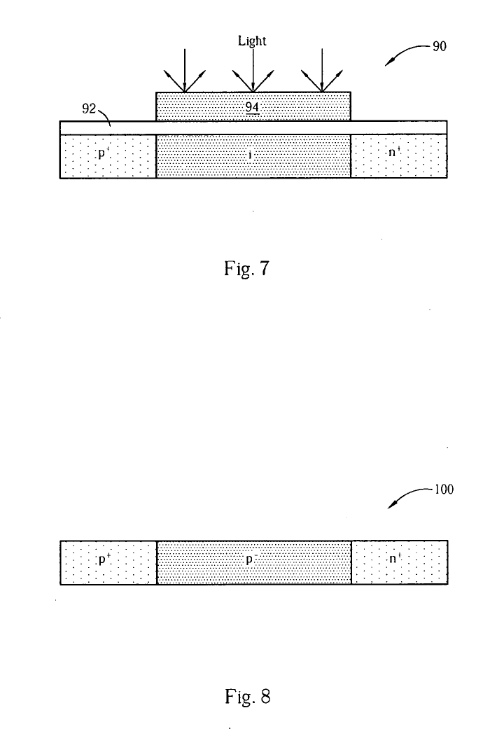

With reference to FIG. 7, FIG. 7 is a schematic, cross-sectional view of another embodiment of a p⁺-i-n⁺ diode element. As shown in FIG.7, the p⁺-i-n⁺ diode element 90 includes an insulating layer 92, e.g. a silicon oxide layer, and a light-shielding layer 94, e.g. a metal layer, disposed thereon. The light-shielding layer 94 can shield the diode element from external light sources to prevent the occurrence of light-induced current in the i region. It is noted that the light-shield layer 94 can also be disposed under the p⁺-i-n⁺ diode element 90 to shield the diode element from a back light source if necessary.

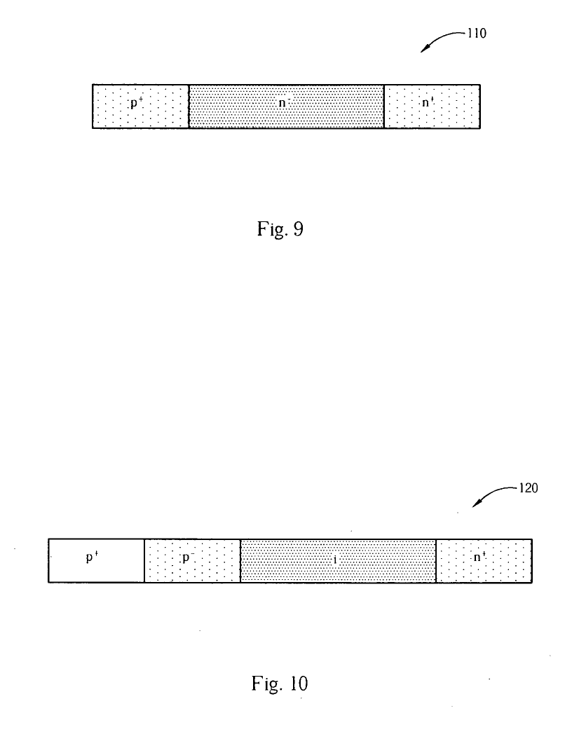

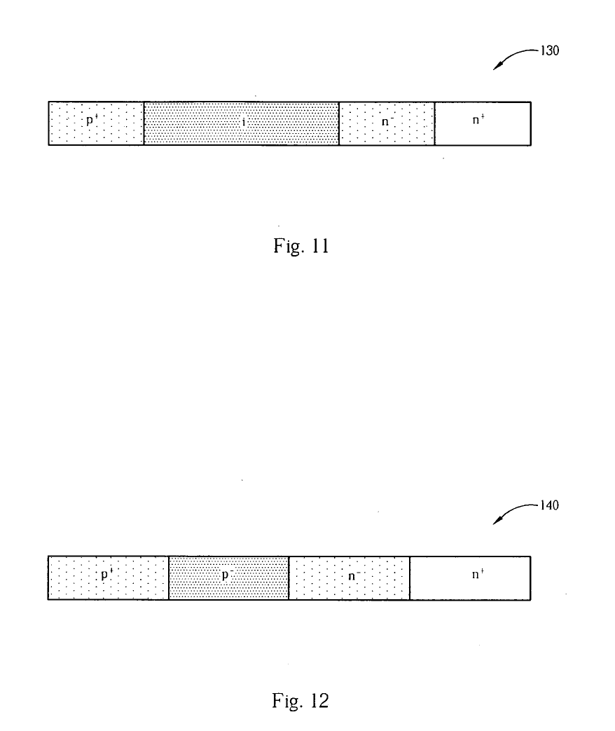

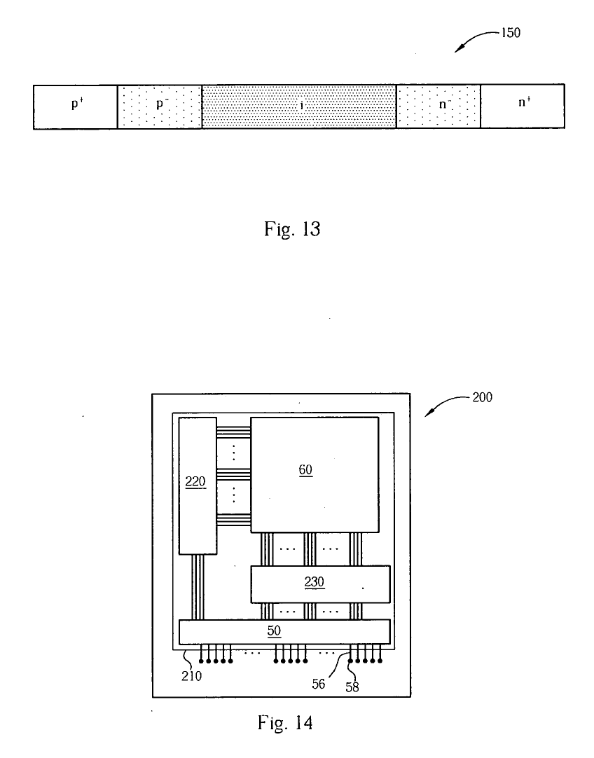

In the aforementioned embodiments, a p⁺-i-n⁺ diode element configuration has been described. However, other thin film diode elements can also be selected. For instance, FIG. 8 to FIG. 13 schematically depict different embodiments of thin film diode elements. In particular, FIG. 8 depicts a p⁺-p⁻-n⁺ diode element 100. FIG.9 depicts a p⁺-n⁻-n⁺ diode element 110. FIG. 10 depicts a p⁺-p⁻-i-n⁺ diode element 120. FIG. 11 depicts a p⁺-i-n⁻-n⁺ diode element 130. FIG. 12 depicts a p⁺-p⁻-n⁻-n⁺ diode element 140. FIG.13 depicts a p⁺-p⁻-i-n⁻-n⁺ diode element 150.

With reference to FIG. 14, FIG. 14 is a schematic diagram illustrating an electronic device 200 incorporating an embodiment of an ESD protection circuit, such as the ESD protection circuit 50 shown in FIG. 4. As shown in FIG. 14, the electronic device 200 includes a display panel 210. The display panel 210 incorporates a main circuit 60, an integrated driver coupled to the main circuit 60, a signal line 56 having an input end 58, and an ESD protection circuit 50. The ESD protection circuit 50 can be coupled to the signal line 56 between the input end 58 and the H-driver 230, and/or between the input end 58 and the V-driver 220. The electronic device 200 can be an LCD, an OLED, or other display devices. The ESD protection circuit 50 includes a plurality of thin film diode elements fabricated by thin film and implanting techniques as described.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A system for providing electrostatic discharge (ESD) protection of a main circuit, the main circuit comprising a signal line having an input end, the system comprising:
a plurality of first-type thin film diode elements coupled to each other in series, the first-type thin film diode elements being electrically connected to the signal line between the input end and the main circuit.

2. The system of claim 1, wherein the first-type thin film diode elements are forward biased when a positive voltage is applied to the input end of the signal line.

3. The system of claim 1, further comprising a plurality of second-type thin film diode elements coupled to each other in series, the second-type thin film diode elements being electrically connected to the signal line between the input end and the main circuit at one end.

4. The system of claim 3, wherein the second-type thin film diode elements are forward biased when a negative voltage is applied to the input end of the signal line.

5. The System of claim 3, wherein the first-type thin film diode elements and the second-type thin film diode elements are selected from a group consisting of p-i-n diode elements, p⁺-i-n⁺ diode elements, p⁺-p⁻-n⁺ diode elements, p⁺-n⁻-n⁺ diode elements, p⁺-p⁻-i-n⁺ diode elements, p⁺-i-n⁻-n⁺ diode elements, p⁺-p⁻-n⁻-n⁺ diode elements, and p⁺-p⁻-i-n⁻-n⁺ diode elements.

6. The System of claim 3, wherein each of the first-type thin film diode elements and each of the second-type thin film diode elements has a single channel.

7. The System of claim 3, wherein at least one of the first-type thin film diode elements and at least one of the second-type thin film diode elements has multiple channels.

8. The System of claim 3, wherein the first-type thin film diode elements are electrically connected to a relatively highest voltage at the other end, and the second-type thin film diode elements are electrically connected to a relatively lowest voltage.

9. The System of claim 1, further comprising a light-shielding layer configured to shield the diode elements from light.

10. The System of claim 1, further comprising means for shielding the diode elements from light.

11. A system for providing ESD protection comprising:
a substrate;
a main circuit supported by the substrate;
a signal line having an input end; and
an ESD protection circuit electrically connected to the input end and the main circuit, the ESD protection circuit comprising a plurality of first-type thin film diode elements coupled to each other in series, the first-type thin film diode elements being electrically connected to the signal line between the input end and the main circuit.

12. The system of claim 11, wherein the signal line is a scan line.

13. The system of claim 11, wherein the signal line is a data line.

14. The system of claim 11, wherein the signal line is a control signal line of an integrated driver.

15. The system of claim 11, further comprising:
a display panel; and
an integrated driver coupled to the display panel, wherein the signal line is a signal line of the display panel.

16. The system of claim 15, further comprising an integrated driver coupled to the display panel.

17. The system of claim 16, wherein the integrated driver comprises a V-driver and an H-driver.

18. A system for providing ESD protection comprising:
a series connected set of thin film diode elements, the set of thin film diode elements comprising two types from the group of:
p-i-n diode elements, p⁺-i-n⁺ diode elements, p⁺-p⁻-n⁺ diode elements, p⁺-n⁻-n⁺ diode elements, p⁺-p⁻-i-n⁺ diode elements, p⁺-i-n⁻-n⁺ diode elements, p⁺-p⁻-n⁻-n⁺ diode elements, and p⁺-p⁻-i-n⁻-n⁺ diode elements.

19. The system of claim 18, wherein a signal line is electrically interconnected at a location between two of the diode elements of the set of thin film diode elements.

20. The system of claim 19, wherein only some of the diode elements are forward biased when a positive voltage is applied to the signal line.
